(19) United States
(12) Patent Application Publication
(10) Pub. No.: US 2025/0377639 A1
(43) Pub. Date: Dec. 11, 2025

(54) CONTROL METHOD FOR SEMICONDUCTOR EQUIPMENT AND CONTROL SYSTEM THEREFOR

(71) Applicant: SAMSUNG ELECTRONICS CO., LTD., Suwon-si (KR)

(72) Inventors: Do-Young KIM, Suwon-si (KR); Hyunjin LEE, Suwon-si (KR); Jinho ON, Suwon-si (KR); Euiseok KUM, Suwon-si (KR); Yohwan JOO, Suwon-si (KR); Sohye YOON, Suwon-si (KR); Byeongeon LEE, Suwon-si (KR)

(73) Assignee: SAMSUNG ELECTRONICS CO., LTD., Suwon-si (KR)

(21) Appl. No.: 19/057,429

(22) Filed: Feb. 19, 2025

(30) Foreign Application Priority Data
Jun. 10, 2024 (KR) 10-2024-0075268

(51) Int. Cl. G05B 13/02; G05B 13/04; H01L 21/67

(52) U.S. Cl. CPC G05B 13/027; G05B 13/042; H01L 21/67276

(57) ABSTRACT

A control method for semiconductor processing equipment, may include: obtaining a first time taken for the semiconductor processing equipment to perform a unit operation according to a first setting value including a plurality of parameters for controlling the semiconductor processing equipment; obtaining a second time taken for the semiconductor processing equipment to perform the unit operation according to a second setting value having at least one parameter different from at least one of the parameters of the first setting value; and controlling the semiconductor processing equipment with the first setting value set, based on the first time being smaller than the second time. The obtaining of the first time may include obtaining the first time taken for the semiconductor processing equipment to perform a plurality of sub-operations constituting the unit operation sequentially, according to a first schedule determined by the first setting value.

### CROSS-REFERENCE TO RELATED APPLICATION

This application claims priority under 35 U.S.C. § 119 to Korean Patent Application No. 10-2024-0075268 filed on Jun. 10, 2024, in the Korean Intellectual Property Office, the disclosures of which are incorporated by reference herein in their entireties.

### BACKGROUND

### 1. Field

Embodiments of the present disclosure described herein relate to a control method for semiconductor processing equipment and a control system therefor.

### 2. Description of Related Art

In general, a semiconductor device is manufactured by repeating the step of depositing several materials on a substrate in the form of a thin film, and patterning it. To this end, there is a need for different processes in several steps, such as a deposition process, an etching process, a cleaning process, and a drying process. In each process, the substrate is mounted and processed on a process chamber which provides an optimal condition for the progress of the process.

In a recently introduced cluster device, a wafer transfer robot loads/unloads wafers into/from respective process chambers in a specified process flow.

Furthermore, the operation of loading/unloading the wafer or projecting various process gases or liquids occurs repeatedly in each process chamber, and the operation in which the transfer robot transfers the wafers occurs without pause. A different time is required for each of such operations. Arrangement in time in such consecutive operations is referred to as an equipment operation schedule.

Finding an optimal equipment operation schedule for any wafer is a very important problem concerning the reduction of the unit cost of producing the semiconductor device. Furthermore, the equipment operation schedule should be determined to reduce a bottleneck problem caused while projecting several wafers into the process chamber continuously.

Meanwhile, various parameters, such as a recipe progress time, a recipe combination, and an operation of each of pieces of hardware included in the cluster device, may affect the productivity of equipment.

### SUMMARY

Thus, recently, to improve the production of semiconductor device according to a rapid increase in demands for the semiconductor device, attempts and studies for optimizing various parameters affecting the equipment operation schedule have been in progress.

Embodiments of the present disclosure provide a control method for semiconductor processing equipment for optimizing an operation schedule of the semiconductor processing equipment to improve productivity.

According to one or more example embodiments, a control method for semiconductor processing equipment, may include: obtaining a first time taken for the semiconductor processing equipment to perform a unit operation according to a first setting value including a plurality of parameters for controlling the semiconductor processing equipment; obtaining a second time taken for the semiconductor processing equipment to perform the unit operation according to a second setting value having at least one parameter different from at least one of the parameters of the first setting value; and controlling the semiconductor processing equipment with the first setting value set, based on the first time being smaller than the second time. The obtaining of the first time may include obtaining the first time taken for the semiconductor processing equipment to perform a plurality of sub-operations constituting the unit operation sequentially, according to a first schedule determined by the first setting value.

According to one or more example embodiments, a control method for semiconductor processing equipment, may include: outputting a plurality of sub-commands corresponding to a plurality of sub-operations constituting a unit operation sequentially according to a first schedule; determining a first time taken for the semiconductor processing equipment to perform the unit operation, based on the plurality of sub-commands output according to the first schedule; outputting the plurality of sub-commands sequentially according to a second schedule different from the first schedule; obtaining a second time taken for the semiconductor processing equipment to perform the unit operation, based on the plurality of sub-commands output according to the second schedule; and transmitting the plurality of sub-commands to the semiconductor processing equipment sequentially according to the first schedule, based on the first time being smaller than the second time.

According to one or more example embodiments, a control method for semiconductor processing equipment, may include: obtaining a first time taken for the semiconductor processing equipment to perform a unit operation according to a first schedule determined by a plurality of parameters for controlling the semiconductor processing equipment; obtaining a second time taken for the semiconductor processing equipment to perform the unit operation according to a second schedule different from the first schedule; and controlling the semiconductor processing equipment according to the first schedule, based on the first time being smaller than the second time. The obtaining of the first time may include obtaining the first time taken for the semiconductor processing equipment to perform a plurality of sub-operations constituting the unit operation sequentially, according to the first schedule.

According to one or more example embodiments, a control method for semiconductor processing equipment, may include: obtaining a plurality of discrete time values for time taken for the semiconductor processing equipment to perform a plurality of operations, respectively; providing a hardware emulator of the semiconductor processing equipment using the plurality of discrete time values; providing a software emulator of control software of the semiconductor processing equipment. The method may further include, using a machine learning model: simulating the plurality of the operations using the hardware emulator and the software emulator using a first set of parameters; obtaining a first time to complete the plurality of the operations using the first set of parameters; simulating the plurality of the operations using the hardware emulator and the software emulator using a second set of parameters different from the first set of parameters; obtaining a second time to complete the plurality of the operations using the second set of parameters; determining which of the first time and the second time is a shorter time; selecting the first set of parameters as a selected set of parameters, based on the first time being the shorter time; and selecting the second set of parameters as the selected set of parameters, based on the second time being the shorter time. The method may further include controlling the semiconductor processing equipment using the selected set of parameters.

### BRIEF DESCRIPTION OF THE DRAWINGS

The above and other aspects, features, and advantages of the present disclosure will be more clearly understood from the following detailed description, taken in conjunction with the accompanying drawings:

FIG. 1 is a block diagram illustrating a control system for semiconductor processing equipment according to one or more embodiments of the present disclosure;

FIG. 2 illustrates a plurality of parameters stored in a control system according to one or more embodiments;

FIG. 3 is a block diagram illustrating a control system which further includes a time calculation module according to one or more embodiments;

FIG. 4 is a block diagram illustrating a control system which further includes a machine learning model according to one or more embodiments;

FIG. 5 is a block diagram illustrating a control system which includes a plurality of pieces of emulation logic according to one or more embodiments;

FIG. 6 is a flowchart illustrating a control method for semiconductor processing equipment according to one or more embodiments;

FIG. 7 is a flowchart illustrating a method for obtaining a first required time according to one or more embodiments;

FIG. 8 is a flowchart illustrating a detailed method for obtaining a first required time according to one or more embodiments;

FIG. 9 is a flowchart illustrating a method for identifying a setting value meeting a predetermined criterion in a machine learning model according to one or more embodiments;

FIG. 10 is a flowchart illustrating a method for determining a required time of semiconductor processing equipment according to different schedules in a machine learning model according to one or more embodiments; and

FIG. 11 is a flowchart illustrating a control method for semiconductor processing equipment according to another embodiment.

### DETAILED DESCRIPTION

Hereinafter, embodiments of the present disclosure will be described clearly and in detail to such an extent that those skilled in the art easily carry out the present disclosure.

The expressions, such as “first”, “second”, “1st”, “2nd”, or the like used in the present disclosure may be used to refer to various components regardless of the order and/or the priority and to distinguish the relevant components from other components, but do not limit the order or importance of the components.

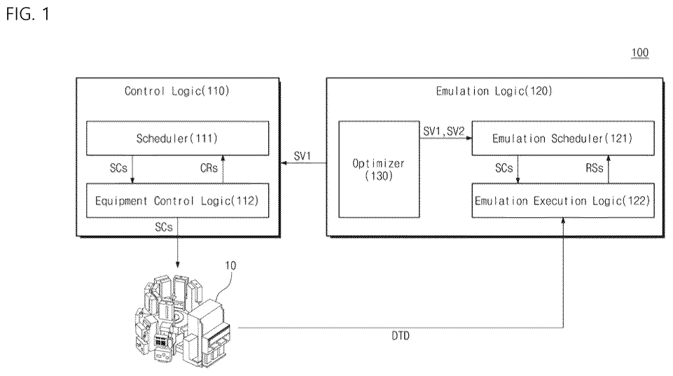

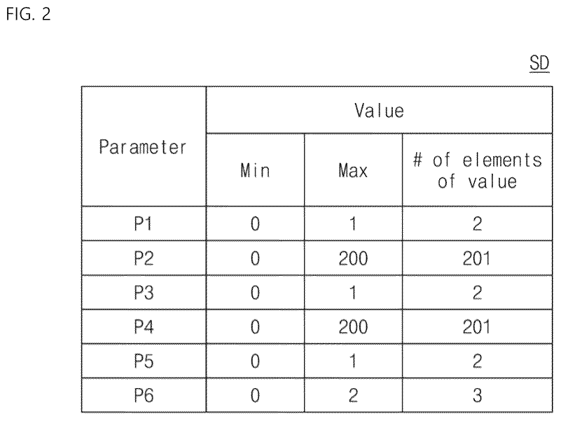

FIG. 1 is a block diagram illustrating a control system for semiconductor processing equipment according to one or more embodiments of the present disclosure. FIG. 2 illustrates a plurality of parameters stored in a control system according to one or more embodiments.

Referring to FIG. 1, a control system 100 according to one or more embodiments may include control logic 110 and emulation logic 120.

The control system 100 may control an operation of semiconductor (processing) equipment 10. In detail, the control system 100 may control the semiconductor processing equipment 10 to perform a unit operation composed of a plurality of sub-operations.

Herein, for example, the unit operation may be understood as an operation for performing a process for a specified number of wafers (e.g., 25 wafers) stored in a front opening unified pod (FOUP).

In other words, the control system 100 may control the semiconductor processing equipment 10 to perform the plurality of sub-operations to proceed with the process for the wafers stored in the FOUP.

in detail, the control system 100 may include the emulation logic 120 which determines a setting value (e.g., a first setting value SV1) for causing the control logic 110 (or a scheduler 111) to control the semiconductor processing equipment 10.

In detail, the emulation logic 120 may determine the setting value (e.g., the first setting value SV1) for controlling the semiconductor processing equipment 10 to perform the unit operation within the shortest time among the plurality of setting values SV1 and SV2.

According to one or more embodiments, the emulation logic 120 may include an emulation scheduler 121, emulation execution logic 122, and an optimizer 130.

Referring to FIGS. 1 and 2, the emulation logic 120 may include the optimizer 130 which stores setting data SD. In detail, the optimizer 130 may store the setting data SD in its internal storage space.

Referring to FIG. 2, the setting data SD according to one or more embodiments may include at least some of a minimum value of each of a plurality of parameters P1 to P6, a maximum value of each of the plurality of parameters P1 to P6, and the number of values of each of the plurality of parameters.

For example, the setting data SD may include a minimum value (“0”) of the first parameter P1, a maximum value (“1”) of the first parameter P1, and the number (“2”) of values of the first parameter P1. For another example, the setting data SD may include a minimum value (“0”) of the second parameter P2, a maximum value (“200”) of the second parameter P2, and the number (“201”) of values of the second parameter P2.

The setting data SD according to another embodiment may further include a time taken for the semiconductor processing equipment 10 to operate, under control of the control logic 110 which uses the plurality of setting values determined by a combination of the plurality of parameters P1 to P6.

The configuration of the setting data SD is not limited to the above-mentioned examples, which may be understood as further including various parameters which may affect a control process for the semiconductor processing equipment 10 and various pieces of data associated with each parameter.

Furthermore, the setting data SD may be referred to as, but not limited to, a design of experiment (DOE).

Furthermore, the emulation logic 120 may include the emulation scheduler 121 which outputs a plurality of sub-commands SCs, according to the schedule determined by the setting values SV1 and SV2.

According to one or more embodiments, the emulation scheduler 121 may determine a schedule for outputting the plurality of sub-commands SCs, based on the setting values SV1 and SV2 delivered from the optimizer 130.

For example, the emulation scheduler 121 may determine a first schedule for outputting the plurality of sub-commands SCs, based on the first setting value SV1. For another example, the emulation scheduler 121 may determine a second schedule for outputting the plurality of sub-commands SCs, based on the second setting value SV2.

Herein, for example, each of the first schedule and the second schedule may include information an order in which each of the plurality of sub-commands SCs is outputted and/or a time point when each of the plurality of sub-commands SCs is outputted.

In addition, the emulation scheduler 121 may output the plurality of sub-commands SCs sequentially according to the determined schedule.

For example, the emulation scheduler 121 may output the plurality of sub-commands SCs sequentially, according to the first schedule determined by the first setting value SV1.

Furthermore, the emulation logic 120 may include the emulation execution logic 122 which outputs a corresponding response RSs, in response to each of the plurality of sub-commands SCs.

According to one or more embodiments, the emulation execution logic 122 may obtain a plurality of discrete time values DTD taken for the semiconductor processing equipment 10 to perform each of the plurality of sub-operations respectively corresponding to the plurality of sub-commands SCs from the semiconductor processing equipment 10.

For example, the emulation execution logic 122 may obtain a first discrete time value taken for the semiconductor processing equipment 10 to perform a first sub-operation corresponding to a first sub-command from the semiconductor processing equipment 10.

In addition, the emulation execution logic 122 may transmit the corresponding response RSs to the emulation scheduler 121, in response to each of the plurality of sub-commands SCs.

In detail, the emulation execution logic 122 may add discrete time values taken for the semiconductor processing equipment 10 to perform each of the plurality of sub-operations sequentially and may transmit the corresponding response RSs, in response to each of the plurality of sub-commands SCs.

Herein, the corresponding response RSs may include data obtained by adding a discrete time value taken to perform a sub-operation corresponding to a specific sub-command input to the emulation execution logic 122 to data about a time point when the specific sub-command is input to the emulation execution logic 122.

For example, the emulation execution logic 122 may output data “5”, which is obtained by adding time “5” taken to perform the first sub-operation corresponding to the first sub-command to time point “0” when the first sub-command is input, as the corresponding response RSs.

For another example, the emulation execution logic 122 may output data “9”, which is obtained by adding time “3” taken to perform a second sub-operation corresponding to a second sub-command to time point “6” when the second sub-command is input, as the corresponding response RSs.

Referring to the above-mentioned configurations, the emulation execution logic 122 may add and output a time taken for the semiconductor processing equipment 10 to perform the plurality of sub-operations to discrete data, in response to the plurality of sub-commands SCs which are output sequentially.

In other words, the emulation execution logic 122 may add and determine a time taken for the semiconductor processing equipment 10 to perform the unit operation according to a specific schedule (or setting value) to discrete data, without waiting during a time when the semiconductor processing equipment 10 actually operates.

As a result, the control system 100 of the present disclosure may minimize a time taken to determine a time when the semiconductor processing equipment 10 performs the unit operation according to each of the plurality of setting values SV1 and SV2.

In addition, the emulation logic 120 may determine a setting value for causing the semiconductor processing equipment 10 to perform the unit operation within the shortest time among the plurality of setting values SV1 and SV2.

For example, the emulation logic 120 may determine a first required time taken for the semiconductor processing equipment 10 to perform the unit operation according to the first schedule determined by the first setting value SV1.

Furthermore, for example, the emulation logic 120 may determine a second required time taken for the semiconductor processing equipment 10 to perform the unit operation according to the second schedule determined by the second setting value SV2.

Furthermore, according to one or more embodiments, when the first required time is smaller than the second required time, the emulation logic 120 may transmit the first setting value SV1 (or the first schedule) to the control logic 110.

Furthermore, the control system 100 may include the control logic 110 which controls an operation of the semiconductor processing equipment 10.

In detail, the control logic 110 may control the operation of the semiconductor processing equipment 10, based on the setting value (e.g., the first setting value SV1) delivered from the emulation logic 120.

According to one or more embodiments, the control logic 110 may include the scheduler 111 and equipment control logic 112.

The scheduler 111 may determine a schedule for outputting a plurality of sub-commands SCs.

In detail, the scheduler 111 may determine the schedule for outputting the plurality of sub-commands SCs, based on the setting values delivered from the emulation logic 120.

Herein, the schedule may include at least some of an order in which the plurality of sub-commands SCs are output and a time point when the plurality of sub-commands SCs are output.

For example, the scheduler 111 may determine the first schedule for outputting the plurality of sub-commands SCs, based on the first setting value SV1 delivered from the emulation logic 120.

In addition, the scheduler 111 may output the plurality of sub-commands SCs sequentially, based on the determined schedule.

In detail, the scheduler 111 may output the plurality of sub-commands SCs sequentially, according to the schedule determined by the setting values delivered from the emulation logic 120.

Furthermore, the control logic 110 may include the equipment control logic 112 which transmits each of the plurality of sub-commands SCs outputted by the scheduler 111 to the semiconductor processing equipment 10.

The equipment control logic 112 according to one or more embodiments may transmit the plurality of sub-commands SCs output from the scheduler 111 to the semiconductor processing equipment 10 sequentially.

Herein, the semiconductor processing equipment 10 may perform a plurality of sub-operations sequentially, in response to each of the plurality of sub-commands SCs transmitted from the equipment control logic 112.

For example, the semiconductor processing equipment 10 may perform the plurality of sub-operations respectively corresponding to the plurality of sub-commands SCs, in response to each of the plurality of sub-commands SCs.

In addition, as the semiconductor processing equipment 10 performs each of the plurality of sub-operations, the equipment control logic 112 may transmit a plurality of completion responses CRs to the scheduler 111.

In addition, the equipment control logic 112 may transmit the plurality of completion responses CRs to the scheduler 111, in response to that the semiconductor processing equipment 10 respectively completes the plurality of sub-operations according to the plurality of sub-commands SCs.

Referring to the above-mentioned configurations, the control logic 110 may control the operation of the semiconductor processing equipment 10 according to the setting value (or the schedule) determined by the emulation logic 120.

In detail, the control logic 110 may control the semiconductor processing equipment 10 according to the setting value (or the schedule) determined that the semiconductor processing equipment 10 may perform the unit operation within the shortest time among the plurality of setting values by the emulation logic 120.

In other words, the control system 100 may optimize an operation schedule for causing the semiconductor processing equipment 10 to perform the plurality of sub-operations.

As a result, the control system 100 according to one or more embodiments of the present disclosure may improve the productivity of the semiconductor processing equipment 10.

Furthermore, the scheduler 111 according to one or more embodiments may include substantially the same configuration as the emulation scheduler 121 included in the emulation logic 120. Furthermore, the scheduler 111 may operate in substantially the same manner as the emulation scheduler 121. In other words, to accurately predict the setting value capable of improving the productivity of the semiconductor processing equipment 10, the emulation scheduler 121 included in the emulation logic 120 and the scheduler 111 included in the control logic 110 may need to be interchangeable.

Thus, the time determined to be taken for the semiconductor processing equipment 10 to perform the unit operation in the emulation logic 120 may be referenced as being substantially the same as a time taken for the semiconductor processing equipment 10 to perform the unit operation actually under control of the control logic 110.

As a result, the control system 100 according to one or more embodiments of the present disclosure may improve a match between the required time of the semiconductor processing equipment 10, which is determined by means of the emulation logic 120, and a time when the semiconductor processing equipment 10 operates under control of the control logic 110.

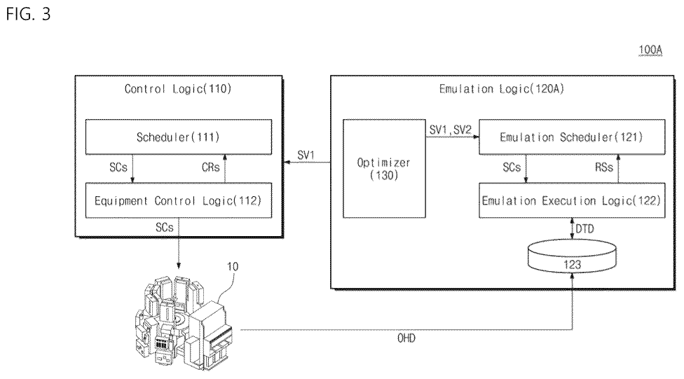

FIG. 3 is a block diagram illustrating a control system which further includes a time calculation module according to one or more embodiments.

Referring to FIG. 3, a control system 100A according to one or more embodiments may include control logic 110 and emulation logic 120A. Furthermore, the emulation logic 120A may include an emulation scheduler 121, emulation execution logic 122, an optimizer 130, and a time calculation module 123.

Herein, the control system 100A shown in FIG. 3 may be understood as an example of a control system 100 shown in FIG. 1. Furthermore, the emulation logic 120A shown in FIG. 3 may be understood as a configuration which further includes the time calculation module 123 in an emulation logic 120 shown in FIG. 1.

Thus, the same reference numeral is used for the configuration which is the same or substantially the same as the above-mentioned configuration, and a description duplicated with the above-mentioned contents will be omitted.

The emulation logic 120A may include the time calculation module 123 which calculates a plurality of discrete time values DTD taken for semiconductor processing equipment 10 to perform a plurality of sub-operations.

According to one or more embodiments, the time calculation module 123 may obtain operation history data OHD of the semiconductor processing equipment 10 from the semiconductor processing equipment 10. In detail, the time calculation module 123 may obtain the operation history data OHD of the semiconductor processing equipment 10 from the semiconductor processing equipment 10 over a specified period.

Herein, the operation history data OHD may include at least some of a type of each of operations performed by at least one piece of hardware included in the semiconductor processing equipment 10 and a required time of each of the operations.

For example, the operation history data OHD may include a time when a robot included in the semiconductor processing equipment 10 performs a specific operation.

Furthermore, for another example, the operation history data OHD may include a time taken to heat or cool a wafer to be a specified temperature in a specific processor chamber in the semiconductor processing equipment 10.

In addition, the time calculation module 123 may calculate the plurality of discrete time values DTD taken for the semiconductor processing equipment 10 to perform each of the plurality of sub-operations, based on the operation history data OHD.

For example, the time calculation module 123 may calculate a first discrete time value taken for the semiconductor processing equipment 10 to perform a first sub-operation, based on the operation history data OHD.

Furthermore, for example, the time calculation module 123 may calculate a second discrete time value taken for the semiconductor processing equipment 10 to perform a second sub-operation, based on the operation history data OHD.

In addition, the time calculation module 123 may output the plurality of calculated discrete time values DTD to the emulation execution logic 122.

According to one or more embodiments, the time calculation module 123 may output at least some of the plurality of discrete time values DTD, according to a request output from the emulation execution logic 122 in response to each of the plurality of sub-commands SCs.

For example, the time calculation module 123 may output a first discrete time value to the emulation execution logic 122, according to a request output from the emulation execution logic 122 in response to a first sub-command.

Also, the time calculation module 123 may output a second discrete time value to the emulation execution logic 122, according to a request output from the emulation execution logic 122 in response to a second sub-command subsequent to the first sub-command.

According to another embodiment, the time calculation module 123 may output the plurality of discrete time values DTD to the emulation execution logic 122, in response to that setting values SV1 and SV2 are output from the optimizer 130.

In addition, the emulation execution logic 122 may transmit a corresponding response RSs to the emulation scheduler 121, based on the plurality of discrete time values DTD.

in detail, the emulation execution logic 122 may add discrete time values taken for the semiconductor processing equipment 10 to perform each of the plurality of sub-operations sequentially and may transmit the corresponding response RSs, in response to each of the plurality of sub-commands SCs.

Herein, the corresponding response RSs may include data obtained by adding a discrete time value taken to perform a sub-operation corresponding to a specific sub-command input to the emulation execution logic 122 to data about a time point when the specific sub-command is input to the emulation execution logic 122.

For example, the emulation execution logic 122 may output data “5”, which is obtained by adding time “5” taken to perform the first sub-operation corresponding to the first sub-command to time point “0” when the first sub-command is input, as the corresponding response RSs.

For another example, the emulation execution logic 122 may output data “9”, which is obtained by adding time “3” taken to perform the second sub-operation corresponding to the second sub-command to time point “6” when the second sub-command is input, as the corresponding response RSs.

Referring to the above-mentioned configurations, the emulation execution logic 122 may add and output a time taken for the semiconductor processing equipment 10 to perform the plurality of sub-operations to discrete data, in response to the plurality of sub-commands SCs which are output sequentially.

In other words, the emulation execution logic 122 may add and determine a time taken for the semiconductor processing equipment 10 to perform the unit operation according to a specific schedule (or setting value) to discrete data, without waiting during a time when the semiconductor processing equipment 10 actually operates.

As a result, the control system 100A of the present disclosure may minimize a time taken to determine a time when the semiconductor processing equipment 10 performs the unit operation according to each of the plurality of setting values SV1 and SV2.

In addition, the emulation logic 120A may determine a setting value for causing the semiconductor processing equipment 10 to perform the unit operation within the shortest time among the plurality of setting values SV1 and SV2.

For example, the emulation logic 120A may determine a first required time taken for the semiconductor processing equipment 10 to perform the unit operation according to a first schedule determined by the first setting value SV1.

Furthermore, for example, the emulation logic 120A may determine a second required time taken for the semiconductor processing equipment 10 to perform the unit operation according to a second schedule determined by the second setting value SV2.

Furthermore, according to one or more embodiments, when the first required time is smaller than the second required time, the emulation logic 120A may transmit the first setting value SV1 (or the first schedule) to the control logic 110.

In addition, the control logic 110 may control an operation of the semiconductor processing equipment 10, based on the setting value transmitted from the emulation logic 120A.

In detail, the control logic 110 may control the semiconductor processing equipment 10 to perform the plurality of sub-operations, according to the schedule determined by the setting value transmitted from the emulation logic 120A.

For example, the control logic 110 may control the semiconductor processing equipment 10 to perform the plurality of sub-operations, according to the first schedule determined by the first setting SV1 transmitted from the emulation logic 120A.

Referring to the above-mentioned configurations, the control logic 110 may control the semiconductor processing equipment 10 according to the setting value (or the schedule) determined that the semiconductor processing equipment 10 may perform the unit operation within the shortest time among the plurality of setting values by the emulation logic 120A.

In other words, the control system 100A may optimize an operation schedule for causing the semiconductor processing equipment 10 to perform the plurality of sub-operations.

As a result, the control system 100A according to one or more embodiments of the present disclosure may improve the productivity of the semiconductor processing equipment 10.

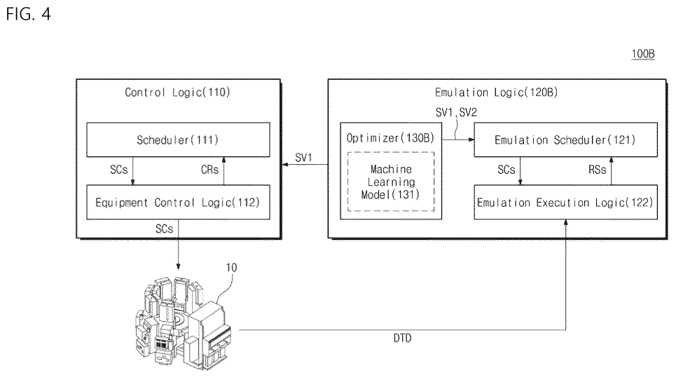

FIG. 4 is a block diagram illustrating a control system which further includes a machine learning model according to one or more embodiments.

Referring to FIG. 4, a control system 100B according to one or more embodiments may include control logic 110 and emulation logic 120B. Furthermore, the emulation logic 120B may include an emulation scheduler 121, emulation execution logic 122, and an optimizer 130B.

Herein, the control system 100B shown in FIG. 4 may be understood as an example of a control system 100 shown in FIG. 1. Furthermore, the emulation logic 120B shown in FIG. 4 may be understood as a configuration which further includes a machine learning model 131 in an emulation logic 120 shown in FIG. 1.

Thus, the same reference numeral is used for the configuration which is the same or substantially the same as the above-mentioned configuration, and a description duplicated with the above-mentioned contents will be omitted.

According to one or more embodiments, the optimizer 130B may include the machine learning model 131. However, it is illustrated in FIG. 4 that the machine learning model 131 is implemented in the optimizer 130B, but not limited thereto. For another example, the machine learning model 131 may be implemented independently of the optimizer 130B in the emulation logic 120B to be connected with the optimizer 130B.

Herein, the machine learning model 131 may be understood as a model (or a module) which performs machine learning.

When controlling semiconductor processing equipment 10 according to a setting value (or a schedule) including a plurality of parameters by means of machine learning, the machine learning model 131 may learn a method for determining a time taken for the semiconductor processing equipment 10 to perform a unit operation.

In detail, the machine learning model 131 may generate a neural network which receives a plurality of discrete time values DTD received from the semiconductor processing equipment 10 and setting values SV1 and SV2 including a plurality of parameters as inputs.

Furthermore, when training (or learning) the neural network and controlling the semiconductor processing equipment 10 according to the setting value or the schedule determined by the setting value, the machine learning model 131 may learn the method for determining the time taken for the semiconductor processing equipment 10 to perform the unit operation.

For example, the machine learning model 131 may include, but is not limited to, various types of models, such as a convolution neural network (CNN), such as GoogleNet, AlexNet, or VGG Network, a region with convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzman machine (RBM), a fully convolutional network, a long short-term memory (LSTM) network, and a classification network.

According to one or more embodiments, the machine learning model 131 may output a plurality of sub-commands SCs, according to each of a plurality of different schedules, which is determined by each of the plurality of setting values.

For example, the machine learning model 131 may generate the plurality of sub-commands SCs, according to a first schedule determined by the first setting value SV1.

Furthermore, the machine learning model 131 may determine a required time by adding discrete time values taken for the semiconductor processing equipment 10 to perform each of a plurality of sub-operations sequentially, in response to the plurality of sub-commands SCs.

Furthermore, the machine learning model 131 may determine the required time by adding the discrete time values taken for the semiconductor processing equipment 10 to perform each of the plurality of sub-operations among the plurality of discrete time values DTD sequentially.

By means of the above-mentioned configurations, the machine learning model 131 may learn a method for determining a required time taken for the semiconductor processing equipment 10 to perform the unit operation, when controlling the semiconductor processing equipment 10 according to each of the plurality of different schedules, which is determined by each of the plurality of setting values.

Furthermore, the machine learning model 131 according to one or more embodiments may identify a setting value (e.g., the first setting value SV1 and the second setting value SV2) in which the required time of the semiconductor processing equipment 10 meets a predetermined criterion among the plurality of setting values. In other words, the machine learning model 131 may select a set of parameters associated with a shorter time to complete operations of the semiconductor processing equipment 10.

In detail, when controlling the semiconductor processing equipment 10 according to the schedule determined by each of the plurality of setting values, the machine learning model 131 may identify the setting value in which the required time of the semiconductor processing equipment 10 meets the predetermined criterion. In other words, the semiconductor processing equipment 10 may be controlled using the selected set of parameters.

Herein, the required time of the semiconductor processing equipment 10 may be referred to the time taken for the semiconductor processing equipment 10 to perform the unit operation.

According to one or more embodiments, when controlling the semiconductor processing equipment 10 according to the schedule determined by each of the plurality of setting values, the machine learning model 131 may identify setting values in which the required time of the semiconductor processing equipment 10 is less than a predetermined threshold.

For example, the machine learning model 131 may identify the first setting value SV1 and the second setting value SV2 in which the required time of the semiconductor processing equipment 10 is less than the predetermined threshold among the plurality of setting values.

According to another embodiment, the machine learning model 131 may identify setting values in which the required time of the semiconductor processing equipment 10 corresponds to required times within a predetermined rate among required times according to the plurality of setting values, among the plurality of setting values.

For example, the machine learning model 131 may identify setting values in which the required time of the semiconductor processing equipment 10 is within upper 50% among the plurality of setting values.

However, the method and/or the criterion in which the machine learning model 131 identifies at least some (e.g., the first setting value SV1 and the second setting value SV2) among the plurality of setting values are/is not limited to the above-mentioned examples.

According to another embodiment, the machine learning model 131 may set priorities to the plurality of setting values, based on required times according to the plurality of setting values.

For example, when it is determined that a first required time according to the first setting value SV1 is smaller than a second required time according to the second setting value SV2 in the machine learning model 131, the machine learning model 131 may assign a priority higher than the second setting value SV2 to the first setting value SV1.

In addition, the machine learning model 131 may transmit the identified setting values SV1 and SV2 to the emulation scheduler 121.

Furthermore, for example, when priorities are assigned to the setting values SV1 and SV2, the emulation scheduler 121 may output the plurality of sub-commands SCs according to the schedule according to each setting value, according to the priority assigned to each setting value.

Referring to the above-mentioned configurations, the emulation logic 120B according to one or more embodiments may identify at least some setting values in which the required time of the semiconductor processing equipment 10 is relatively small among the plurality of setting values using the machine learning model 131.

In addition, the emulation logic 120B may determine a required time taken for the semiconductor processing equipment 10 to perform a unit operation according to the schedule determined by each of the setting values SV1 and SV2 identified by means of the machine learning model 131.

As a result, the control system 100B according to one or more embodiments of the present disclosure may reduce a time taken to determine a setting value (or a schedule) for causing the semiconductor processing equipment 10 to perform the unit operation within the shortest time among the plurality of setting values.

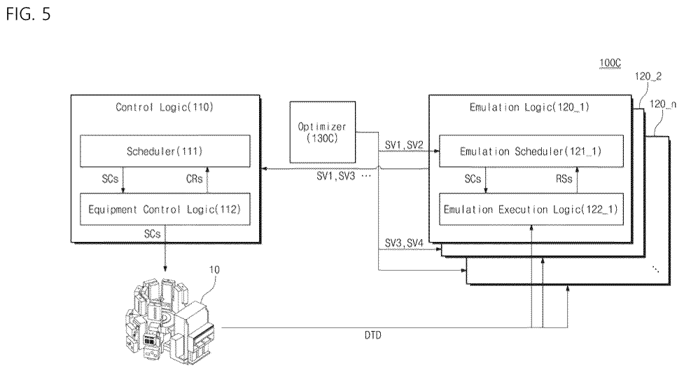

FIG. 5 is a block diagram illustrating a control system which includes a plurality of pieces of emulation logic according to one or more embodiments.

Referring to FIG. 5, a control system 100C according to one or more embodiments may include control logic 110, an optimizer 130C, and a plurality of pieces of emulation logic 120_1 to 120_n.

Herein, the control system 100C shown in FIG. 5 may be understood as an example of a control system 100 shown in FIG. 1. Thus, the same reference numeral is used for the configuration which is the same or substantially the same as the above-mentioned configuration, and a description duplicated with the above-mentioned contents will be omitted.

The control system 100C may include the optimizer 130C which identifies setting values SV1, SV2, SV3, and SV4 meeting a predetermined criterion among a plurality of setting values.

In detail, the optimizer 130C according to one or more embodiments may identify the first to fourth setting values SV1 to SV4 in which the required time of the semiconductor processing equipment 10 is less than a predetermined threshold among the plurality of setting values.

According to another embodiment, the optimizer 130C may identify setting values in which the required time of the semiconductor processing equipment 10 corresponds to required times within a predetermined rate among required times according to the plurality of setting values, among the plurality of setting values.

For example, the optimizer 130C may identify the first to fourth setting values SV1 to SV4 in which the required time of the semiconductor processing equipment 10 is within upper 20% among the plurality of setting values.

In addition, the optimizer 130C may transmit the identified setting values SV1, SV2, SV3, and SV4 to the plurality of pieces of emulation logic 120_1 to 120_n.

In detail, the optimizer 130C may transmit a predetermined number of setting values among the identified setting values SV1, SV2, SV3, and SV4 to each of the plurality of pieces of emulation logic 120_1 to 120_n.

For example, the optimizer 130C may transmit the first setting value SV1 and the second setting value SV2 among the identified setting values SV1, SV2, SV3, and SV4 to the first emulation logic 120_1.

Furthermore, for example, the optimizer 130C may transmit the third setting value SV3 and the fourth setting value SV4 among the identified setting values SV1, SV2, SV3, and SV4 to the second emulation logic 120_2.

However, configurations and the number of setting values transmitted to each of the plurality of pieces of emulation logic 120_1 to 120_n by the optimizer 130C are not limited to the above-mentioned examples.

Furthermore, the optimizer 130C is implemented as a configuration independent of the plurality of pieces of emulation logic 120_1 to 120_n in FIG. 5 to be connected with the plurality of pieces of emulation logic 120_1 to 120_n, but not limited thereto.

The optimizer 130C according to another embodiment may be implemented in one of the plurality of pieces of emulation logic 120_1 to 120_n.

According to another embodiment, the optimizer 130C may be implemented as a plurality of configurations in each of the plurality of pieces of emulation logic 120_1 to 120_n.

Furthermore, the control system 100C may include the plurality of pieces of emulation logic 120_1 to 120_n, each of which determines a required time of the semiconductor processing equipment 10 according to a schedule determined by a different setting value.

In detail, the control system 100C may include the first emulation logic 120_1 which determines a time taken for the semiconductor processing equipment 10 to perform a unit operation according to each of the first setting value SV1 and the second setting value SV2.

For example, the first emulation logic 120_1 may determine a first required time taken for the semiconductor processing equipment 10 to perform the unit operation, according to a first schedule determined by the first setting value SV1.

Furthermore, for example, the first emulation logic 120_1 may determine a second required time taken for the semiconductor processing equipment 10 to perform the unit operation, according to a second schedule determined by the second setting value SV2.

Herein, for example, the first emulation logic 120_1 may be understood as being substantially the same as an emulation logic 120 shown in FIG. 1.

Furthermore, the control system 100C may include the second emulation logic 120-2 which determines a time taken for the semiconductor processing equipment 10 to perform the unit operation according to each of the third setting value SV3 and the fourth setting value SV4.

For example, the second emulation logic 120-2 may determine a third required time taken for the semiconductor processing equipment 10 to perform the unit operation, according to a third schedule determined by the third setting value SV3.

Furthermore, for example, the second emulation logic 120_2 may determine a fourth required time taken for the semiconductor processing equipment 10 to perform the unit operation, according to a fourth schedule determined by the fourth setting value SV4.

According to one or more embodiments, at least two or more of the plurality of pieces of emulation logic 120_1 to 120_n may operate in parallel.

For example, while the first emulation logic 120_1 determines the first required time, the second emulation logic 120_2 may perform an operation for determining the third required time.

Furthermore, for example, while the first emulation logic 120_1 determines the second required time, the second emulation logic 120_2 may perform an operation for determining the fourth required time.

Referring to the above-mentioned configurations, at least two or more of the plurality of pieces of emulation logic 120_1 to 120_n may operate such that at least a portion of each operation is performed at the same time.

As a result, the control system 100C according to one or more embodiments of the present disclosure may reduce a time necessary to determine required times taken for the semiconductor processing equipment 10 to perform the unit operation, according to each of the plurality of setting values.

Furthermore, each of the plurality of pieces of emulation logic 120_1 to 120_n may transmit a setting value corresponding to the smallest required time among the determined required times to the control logic 110.

For example, when the first required time is smaller than the second required time, the first emulation logic 120_1 may transmit the first setting value SV1 corresponding to the first required time to the control logic 110.

Furthermore, for example, when the third required time is smaller than the fourth required time, the second emulation logic 120_2 may transmit the third setting value SV3 corresponding to the third required time to the control logic 110.

Furthermore, the control logic 110 according to one or more embodiments may identify a setting value corresponding to the smallest required time among the setting values transmitted from the plurality of pieces of emulation logic 120_1 to 120_n.

For example, when the first required time is smaller than the third required time, the control logic 110 may identify the first setting value SV1 corresponding to the first required time.

In addition, the control logic 110 may control the semiconductor processing equipment 10, based on the setting value corresponding to the smallest required time.

For example, when the first required time is smaller than the third required time, a scheduler 111 may output a plurality of sub-commands SCs sequentially, according to the first schedule determined by the first setting value SV1.

In addition, equipment control logic 112 may transmit the plurality of sub-commands SCs output according to the first schedule to the semiconductor processing equipment 10 sequentially.

As a result, as the semiconductor processing equipment 10 performs a plurality of sub-operations according to the first schedule, the control logic 110 may control the semiconductor processing equipment 10 to perform the unit operation.

In other words, the control system 100C may optimize an operation schedule for causing the semiconductor processing equipment 10 to perform the plurality of sub-operations.

By means of the above-mentioned configurations, the control system 100C according to one or more embodiments of the present disclosure may improve the productivity of the semiconductor processing equipment 10.

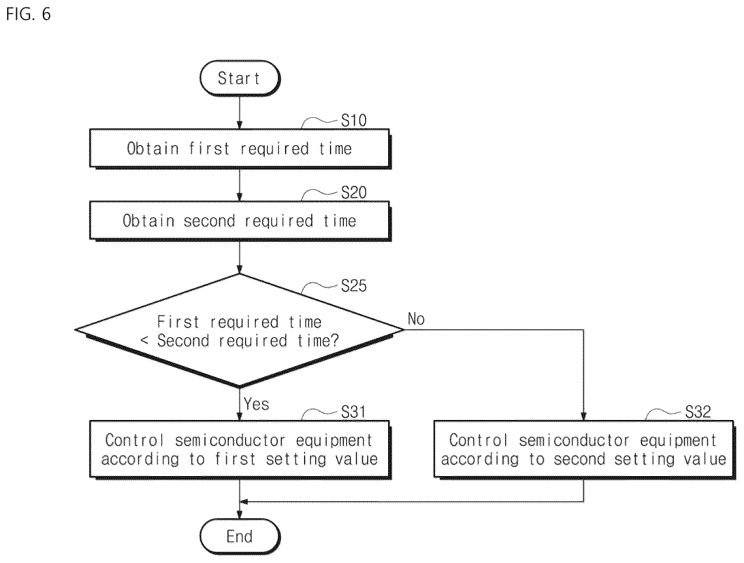

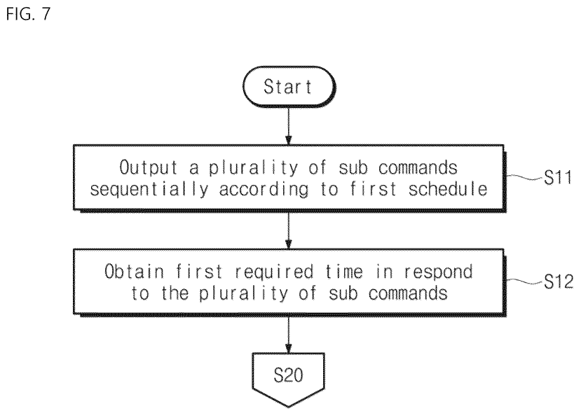

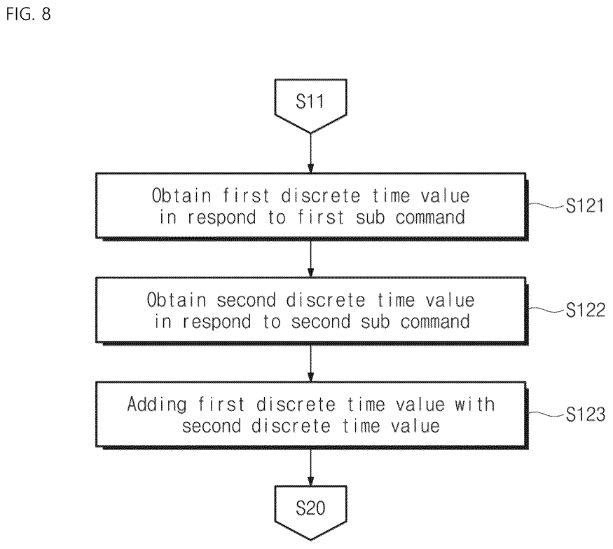

FIG. 6 is a flowchart illustrating a control method for semiconductor processing equipment according to one or more embodiments. FIG. 7 is a flowchart illustrating a method for obtaining a first required time according to one or more embodiments. FIG. 8 is a flowchart illustrating a detailed method for obtaining a first required time according to one or more embodiments.

Referring to FIG. 6, a control system 100 (or emulation logic 120) according to one or more embodiments may determine a setting value for minimizing a time taken for semiconductor processing equipment 10 to perform a unit operation.

In operation S10, the control system 100 according to one or more embodiments may obtain a first required time.

In detail, when the semiconductor processing equipment 10 performs a plurality of sub-operations according to a first schedule determined by a first setting value SV1, the control system 100 may obtain the first required time taken for the semiconductor processing equipment 10 to perform the unit operation.

Referring to FIG. 7, the control system 100 according to one or more embodiments may obtain the first required time, based on a plurality of sub-commands SCs which are output according to the first schedule.

In operation S11, the control system 100 may output the plurality of sub-commands SCs sequentially according to the first schedule.

Herein, for example, the first schedule may include information about an order in which each of the plurality of sub-commands SCs is outputted and a time point when each of the plurality of sub-commands SCs is outputted.

Furthermore, herein, the first schedule may be determined by a first setting value SV1 or at least some of a plurality of parameters P1 to P6 included in the first setting value SV1.

In operation S12, the control system 100 may obtain the first required time, in response to the plurality of sub-commands SCs which are output sequentially according to the first schedule.

In detail, the control system 100 may obtain the first required time taken for the semiconductor processing equipment 10 to perform the unit operation, in response to the plurality of sub-commands SCs which are output sequentially according to the first schedule.

Herein, referring to FIG. 8, the control system 100 according to one or more embodiments may obtain the first required time by adding a plurality of discrete time values DTD taken for the semiconductor processing equipment 10 to perform the plurality of sub-operations corresponding to the plurality of sub-commands SCs.

In operation S121, the control system 100 may obtain a first discrete time value in response to a first sub-command.

In detail, the control system 100 may obtain the first discrete time value taken for the semiconductor processing equipment 10 to perform a first sub-operation corresponding to the first sub-command, in response to the first sub-command.

Herein, the control system 100 may obtain the first discrete time value from operation history data OHD of the semiconductor processing equipment 10.

In detail, the control system 100 may obtain the first discrete time value taken for the semiconductor processing equipment 10 to perform the first sub-operation, based on the operation history data OHD obtained from the semiconductor processing equipment 10.

In operation S122, the control system 100 may obtain a second discrete time value in response to a second sub-command.

In detail, after obtaining the first discrete time value, the control system 100 may obtain the second discrete time value taken for the semiconductor processing equipment 10 to perform the second sub-operation corresponding to the second sub-command, in response to the second sub-command.

In addition, in operation S123, the control system 100 may add the first discrete time value to the second discrete time value.

For example, the control system 100 may output data “5” obtained by adding time “5” taken to perform the first sub-operation corresponding to the first sub-command to time point “0” when the first sub-command is input.

Furthermore, the control system 100 may output data “9” obtained by adding time “3” taken to perform the second sub-operation corresponding to the second sub-command to time point “6” when the second sub-command is input.

Referring to the above-mentioned configurations, the control system 100 may add and output a time taken for the semiconductor processing equipment 10 to perform the plurality of sub-operations to discrete data, in response to the plurality of sub-commands SCs which are output sequentially.

In other words, the control system 100 may add and determine a time taken for the semiconductor processing equipment 10 to perform the unit operation according to a specific schedule (or setting value) to discrete data, without waiting during a time when the semiconductor processing equipment 10 operates actually.

As a result, the control system 100 of the present disclosure may minimize a time taken to determine a time when the semiconductor processing equipment 10 performs the unit operation according to each of the plurality of setting values SV1 and SV2.

In addition, in operation S20, the control system 100 may obtain a second required time.

In detail, the control system 100 may determine the second required time taken for the semiconductor processing equipment 10 to perform the unit operation according to a second schedule determined by the second setting value SV2.

For example, the control system 100 may output the plurality of sub-commands SCs sequentially according to the second schedule.

Herein, the second schedule may be determined by the second setting value SV2 or at least some of a plurality of parameters P1 to P6 included in the second setting value SV2.

For example, the control system 100 may add discrete time values taken for the semiconductor processing equipment 10 to perform the plurality of sub-operations sequentially, in response to the plurality of sub-commands SCs which are output sequentially according to the second schedule.

As a result, the control system 100 may obtain the second required time taken for the semiconductor processing equipment 10 to perform the unit operation according to the second setting value SV2 (or the second schedule).

In addition, in operation S25, the control system 100 may determine whether the first required time is smaller than the second required time.

For example, the control system 100 may determine whether the semiconductor processing equipment 10 completes the unit operation within a relatively faster time when controlling the semiconductor processing equipment 10 according to the first setting value SV1 (or the first schedule) than when controlling the semiconductor processing equipment 10 according to the second setting value SV2 (or the second schedule).

According to one or more embodiments, when the first required time is smaller than the second required time, in operation S31, the control system 100 may control the semiconductor processing equipment 10 according to the first setting value SV1 (or the first schedule).

In detail, when the first required time is smaller than the second required time, the control system 100 may transmit the plurality of sub-commands SCs to the semiconductor processing equipment 10 sequentially according to the first schedule.

Herein, the semiconductor processing equipment 10 may perform the plurality of sub-operations respectively corresponding to the plurality of sub-commands SCs sequentially, in response to the plurality of sub-commands SCs which are transmitted sequentially according to the first schedule.

According to another embodiment, when the first required time is greater than or equal to the second required time, in operation S32, the control system 100 may control the semiconductor processing equipment 10 according to the second setting value SV2 (or the second schedule).

In detail, when the first required time is greater than or equal to the second required time, the control system 100 may transmit the plurality of sub-commands SCs to the semiconductor processing equipment 10 sequentially according to the second schedule.

Herein, the semiconductor processing equipment 10 may perform the plurality of sub-operations respectively corresponding to the plurality of sub-commands SCs sequentially, in response to the plurality of sub-commands SCs which are transmitted sequentially according to the second schedule.

Referring to the above-mentioned configurations, the control system 100 may determine a setting value for causing the semiconductor processing equipment 10 to perform the unit operation within the shortest time among the plurality of setting values.

In addition, the control system 100 may control the semiconductor processing equipment 10 according to the setting value (or the schedule) determined that the semiconductor processing equipment 10 may perform the unit operation within the shortest time.

In other words, the control system 100 may optimize an operation schedule for causing the semiconductor processing equipment 10 to perform the plurality of sub-operations.

As a result, the control system 100 according to one or more embodiments of the present disclosure may improve the productivity of the semiconductor processing equipment 10.

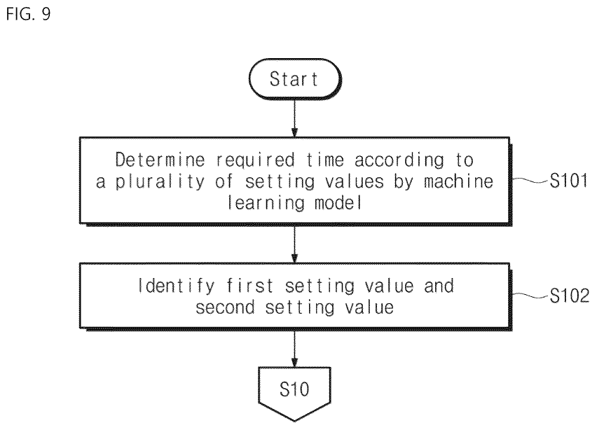

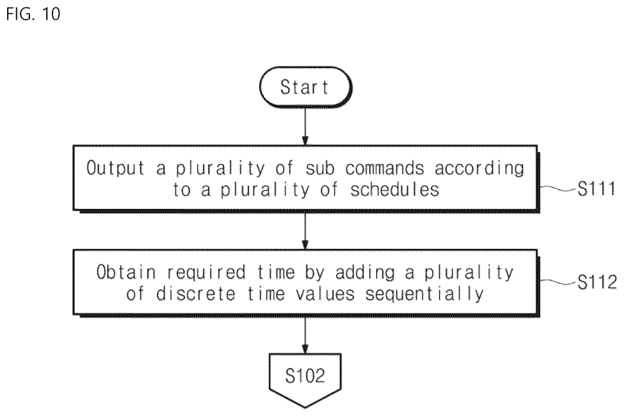

FIG. 9 is a flowchart illustrating a method for identifying a setting value meeting a predetermined criterion in a machine learning model according to one or more embodiments. FIG. 10 is a flowchart illustrating a method for determining a required time of semiconductor processing equipment according to different schedules in a machine learning model according to one or more embodiments.

Referring to FIGS. 9 and 10 together, a control system 100 according to one or more embodiments may reduce a time taken to identify a setting value in which semiconductor processing equipment 10 may perform a unit operation within the shortest duration among a plurality of setting values, using a machine learning model 131.

In FIGS. 9 and 10, the operation performed by the control system 100 may be understood as being performed by the machine learning model 131.

Referring to FIG. 9, the control system 100 may determine a required time of the semiconductor processing equipment 10 according to the plurality of setting values, using the machine learning model 131.

According to one or more embodiments, in operation S101, the control system 100 may determine required times taken for the semiconductor processing equipment 10 to perform a unit operation according to a plurality of different schedules determined by the plurality of setting values, using the machine learning model 131.

In detail, referring to FIG. 10, in operation S111, the control system 100 according to one or more embodiments may output a plurality of sub-commands SCs, according to each of the plurality of different schedules, which is determined by each of the plurality of setting values.

For example, the control system 100 may generate the plurality of sub-commands SCs, according to a first schedule determined by a first setting value SV1.

In operation S112, the control system 100 according to one or more embodiments may obtain a required time by adding a plurality of discrete time values.

In detail, the control system 100 may obtain the required time by adding discrete time values taken for the semiconductor processing equipment 10 to perform each of a plurality of sub-operations sequentially, in response to the plurality of sub-commands SCs.

For example, the control system 100 may obtain a first required time by adding the discrete time values taken for the semiconductor processing equipment 10 to perform each of the plurality of sub-operations among a plurality of discrete time values DTD sequentially according to the first schedule.

By means of the above-mentioned configurations, the control system 100 may learn a method for determining a required time taken for the semiconductor processing equipment 10 to perform the unit operation, when controlling the semiconductor processing equipment 10 according to each of the plurality of different schedules, which is determined by each of the plurality of setting values.

Furthermore, in operation S102, the control system 100 according to one or more embodiments may identify a first setting value SV1 and a second setting value SV2 among the plurality of setting values.

In detail, the control system 100 may identify the first setting value SV1 and the second setting value SV2 in which the required time of the semiconductor processing equipment 10 meets a predetermined criterion among the plurality of setting values.

When controlling the semiconductor processing equipment 10 according to the schedule determined by each of the plurality of setting values, the control system 100 may identify the setting value in which the required time of the semiconductor processing equipment 10 meets the predetermined criterion.

According to one or more embodiments, when controlling the semiconductor processing equipment 10 according to the schedule determined by each of the plurality of setting values, the control system 100 may identify the first setting value SV1 and the second setting value SV2 in which the required time of the semiconductor processing equipment 10 is less than a predetermined threshold.

According to another embodiment, the control system 100 may identify the first setting value SV1 and the second setting value SV2 in which the required time of the semiconductor processing equipment 10 corresponds to required times within a predetermined rate among required times according to the plurality of setting values, among the plurality of setting values.

In addition, the control system 100 may determine a required time of the semiconductor processing equipment 10 according to a different schedule determined by each of the identified setting values SV1 and SV2.

Referring to the above-mentioned configurations, the control system 100 according to one or more embodiments may identify at least some setting values in which the required time of the semiconductor processing equipment 10 is relatively small among the plurality of setting values using the machine learning model 131.

In addition, the control system 100 may determine a required time taken for the semiconductor processing equipment 10 to perform the unit operation according to the schedule determined by each of the setting values SV1 and SV2 identified by means of the machine learning model 131.

As a result, the control system 100 according to one or more embodiments of the present disclosure may reduce a time taken to determine a setting value (or a schedule) for causing the semiconductor processing equipment 10 to perform the unit operation within the shortest time among the plurality of setting values.

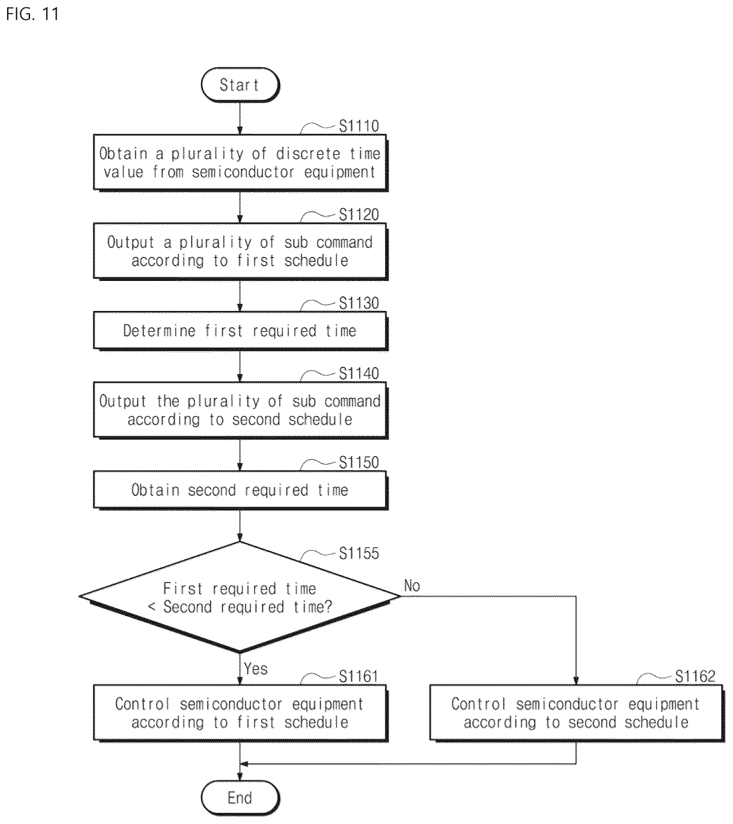

FIG. 11 is a flowchart illustrating a control method for semiconductor processing equipment according to another embodiment.

Referring to FIG. 11, a control system 100 (or emulation logic 120) according to one or more embodiments may determine a schedule for minimizing a time taken for semiconductor processing equipment 10 to perform a unit operation.

In operation S1110, the control system 100 may obtain a plurality of discrete time values DTD taken for the semiconductor processing equipment 10 to perform a plurality of sub-operations from the semiconductor processing equipment 10.

For example, the control system 100 may obtain a first discrete time value taken for the semiconductor processing equipment 10 to perform a first sub-operation from the semiconductor processing equipment 10.

Furthermore, for example, the control system 100 may obtain a second discrete time value taken for the semiconductor processing equipment 10 to perform a second sub-operation from the semiconductor processing equipment 10.

In operation S1120, the control system 100 may output the plurality of sub-commands SCs sequentially according to a first schedule. Herein, for example, the first schedule may include information about an order in which each of the plurality of sub-commands SCs is outputted and a time point when each of the plurality of sub-commands SCs is outputted.

In operation S1130, the control system 100 according to one or more embodiments may obtain a first required time.

In detail, the control system 100 may obtain the first required time taken for the semiconductor processing equipment 10 to perform the plurality of sub-operations, in response to the plurality of sub-commands SCs which are output sequentially according to the first schedule.

Herein, the first required time may be understood as a time taken for the semiconductor processing equipment 10 to perform the unit operation composed of the plurality of sub-operations.

In other words, the control system 100 may obtain the first required time taken for the semiconductor processing equipment 10 to perform the unit operation, in response to the plurality of sub-commands SCs which are output sequentially according to the first schedule.

According to one or more embodiments, the control system 100 may obtain the first required time by adding a plurality of discrete time values DTD taken for the semiconductor processing equipment 10 to perform the plurality of sub-operations corresponding to the plurality of sub-commands SCs.

For example, the control system 100 may obtain a first discrete time value in response to a first sub-command.

In detail, the control system 100 may obtain the first discrete time value taken for the semiconductor processing equipment 10 to perform a first sub-operation corresponding to the first sub-command, in response to the first sub-command.

Herein, the control system 100 may obtain the first discrete time value taken for the semiconductor processing equipment 10 to perform the first sub-operation, based on operation history data OHD obtained from the semiconductor processing equipment 10.

Furthermore, for example, the control system 100 may obtain a second discrete time value in response to a second sub-command.

In detail, after obtaining the first discrete time value, the control system 100 may obtain the second discrete time value taken for the semiconductor processing equipment 10 to perform the second sub-operation corresponding to the second sub-command, in response to the second sub-command.

In addition, the control system 100 may add the first discrete time value to the second discrete time value.

For example, the control system 100 may output data “5” obtained by adding time “5” taken to perform the first sub-operation corresponding to the first sub-command to time point “0” when the first sub-command is input.

Furthermore, the control system 100 may output data “9” obtained by adding time “3” taken to perform the second sub-operation corresponding to the second sub-command to time point “6” when the second sub-command is input.

Referring to the above-mentioned configurations, the control system 100 may add and output a time taken for the semiconductor processing equipment 10 to perform the plurality of sub-operations to discrete data, in response to the plurality of sub-commands SCs which are output sequentially.

In other words, the control system 100 may add and determine a time taken for the semiconductor processing equipment 10 to perform the unit operation according to a specific schedule to discrete data, without waiting during a time when the semiconductor processing equipment 10 operates actually.

As a result, the control system 100 of the present disclosure may minimize a time taken to determine a time when the semiconductor processing equipment 10 performs the unit operation according to each of the different schedules.

In operation S1140, the control system 100 may output the plurality of sub-commands SCs sequentially according to the first schedule. Herein, for example, the second schedule may include information about an order in which each of the plurality of sub-commands SCs is outputted and a time point when each of the plurality of sub-commands SCs is outputted.

In operation S1150, the control system 100 may obtain a second required time.

In detail, the control system 100 may determine the second required time taken for the semiconductor processing equipment 10 to perform the unit operation according to the second schedule.

For example, the control system 100 may output the plurality of sub-commands SCs sequentially according to the second schedule.

For example, the control system 100 may add discrete time values taken for the semiconductor processing equipment 10 to perform the plurality of sub-operations sequentially, in response to the plurality of sub-commands SCs which are output sequentially according to the second schedule.

As a result, the control system 100 may obtain the second required time taken for the semiconductor processing equipment 10 to perform the unit operation according to the second schedule.

In addition, in operation S1155, the control system 100 may determine whether the first required time is smaller than the second required time.

For example, the control system 100 may determine whether the semiconductor processing equipment 10 completes the unit operation within a relatively faster time when controlling the semiconductor processing equipment 10 according to the first schedule than when controlling the semiconductor processing equipment 10 according to the second schedule.

According to one or more embodiments, when the first required time is smaller than the second required time, in operation S1161, the control system 100 may control the semiconductor processing equipment 10 according to the first schedule.

In detail, when the first required time is smaller than the second required time, the control system 100 may transmit the plurality of sub-commands SCs to the semiconductor processing equipment 10 sequentially according to the first schedule.

Herein, the semiconductor processing equipment 10 may perform the plurality of sub-operations respectively corresponding to the plurality of sub-commands SCs sequentially, in response to the plurality of sub-commands SCs which are transmitted sequentially according to the first schedule.

In other words, when the first required time is smaller than the second required time, the control system 100 may control the semiconductor processing equipment 10 to perform the unit operation according to the first schedule.

According to another embodiment, when the first required time is greater than or equal to the second required time, in operation S1162, the control system 100 may control the semiconductor processing equipment 10 according to the second schedule.

In detail, when the first required time is greater than or equal to the second required time, the control system 100 may transmit the plurality of sub-commands SCs to the semiconductor processing equipment 10 sequentially according to the second schedule.

Herein, the semiconductor processing equipment 10 may perform the plurality of sub-operations respectively corresponding to the plurality of sub-commands SCs sequentially, in response to the plurality of sub-commands SCs which are transmitted sequentially according to the second schedule.

In other words, when the first required time is greater than or equal to the second required time, the control system 100 may control the semiconductor processing equipment 10 to perform the unit operation according to the second schedule.

Referring to the above-mentioned configurations, the control system 100 may determine a schedule for causing the semiconductor processing equipment 10 to perform the unit operation within the shortest time among the plurality of setting values.

In addition, the control system 100 may control the semiconductor processing equipment 10 according to the schedule determined that the semiconductor processing equipment 10 may perform the unit operation within the shortest time.

In other words, the control system 100 may optimize an operation schedule for causing the semiconductor processing equipment 10 to perform the plurality of sub-operations.

As a result, the control system 100 according to one or more embodiments of the present disclosure may improve the productivity of the semiconductor processing equipment 10.

Meanwhile, the control system 100 or the control method according to one or more embodiments of the present disclosure may be implemented in the form of a product including a computer-readable program code stored in a computer-readable medium or the like. The computer-readable program code may be provided to processors of various computers or other data processing devices. The computer-readable medium may be a computer-readable signal medium or a computer-readable storage medium. The computer-readable storage medium may be any tangible medium capable of storing or including a program in an instruction execution system, equipment or device or accessing it to store or include the program. For example, the computer-readable medium may be provided in the form of a non-transitory storage medium. Herein, “non-transitory” only means that the storage medium does not include a signal and is tangible and does not distinguish that data is semi-permanently or temporarily stored in the storage medium.

As described above, the control system 100 according to one or more embodiments of the present disclosure may add and output a time taken for the semiconductor processing equipment 10 to perform the plurality of sub-operations to discrete data, in response to the plurality of sub-commands SCs which are output sequentially.

In other words, the control system 100 may add and determine a time taken for the semiconductor processing equipment 10 to perform the unit operation according to a specific schedule to discrete data, without waiting during a time when the semiconductor processing equipment 10 operates actually.

As a result, the control system 100 of the present disclosure may minimize a time taken to determine a time when the semiconductor processing equipment 10 performs the unit operation according to each of the plurality of setting values SV1 and SV2.

Furthermore, the control system 100 according to one or more embodiments may control the semiconductor processing equipment 10 according to the setting value (or the schedule) determined that the semiconductor processing equipment 10 may perform the unit operation within the shortest time among the plurality of setting values.

In other words, the control system 100 may optimize an operation schedule for causing the semiconductor processing equipment 10 to perform the plurality of sub-operations.

As a result, the control system 100 according to one or more embodiments of the present disclosure may improve the productivity of the semiconductor processing equipment 10.

Furthermore, the control system 100 according to one or more embodiments may identify at least some setting values in which the required time of the semiconductor processing equipment 10 is relatively small among the plurality of setting values using a machine learning model 131.

In addition, the control system 100 may determine a required time taken for the semiconductor processing equipment 10 to perform the unit operation according to the schedule determined by each of the setting values SV1 and SV2 identified by means of the machine learning model 131.

As a result, the control system 100 according to one or more embodiments of the present disclosure may reduce a time taken to determine a setting value (or a schedule) for causing the semiconductor processing equipment 10 to perform the unit operation within the shortest time among the plurality of setting values.

The control method according to one or more embodiments of the present disclosure may improve the productivity of the semiconductor processing equipment.

The present disclosure may include embodiments in which a design is changed simply or which are easily changed, other than the above-mentioned embodiments. Furthermore, the present disclosure may include technologies capable of being easily modified and executed using embodiments. Thus, the scope of the present disclosure is not limited and determined to the embodiments described above and should be determined by the following claims and equivalents with the claims of the present disclosure.

What is claimed is:

1. A control method for semiconductor processing equipment, the control method comprising:
obtaining a first time taken for the semiconductor processing equipment to perform a unit operation according to a first setting value comprising a plurality of parameters for controlling the semiconductor processing equipment;
obtaining a second time taken for the semiconductor processing equipment to perform the unit operation according to a second setting value having at least one parameter different from at least one of the parameters of the first setting value; and
controlling the semiconductor processing equipment with the first setting value set, based on the first time being smaller than the second time,
wherein the obtaining of the first time comprises obtaining the first time taken for the semiconductor processing equipment to perform a plurality of sub-operations constituting the unit operation sequentially, according to a first schedule determined by the first setting value.

2. The control method of claim 1, wherein the obtaining of the first time comprises:
outputting a plurality of sub-commands respectively corresponding to the plurality of sub-operations sequentially, according to the first schedule; and
obtaining the first time taken for the semiconductor processing equipment to perform the plurality of sub-operations sequentially, based on the plurality of sub-commands.

3. The control method of claim 2, wherein the controlling of the semiconductor processing equipment according to the first schedule comprises transmitting the plurality of sub-commands to the semiconductor processing equipment sequentially according to the first schedule.

4. The control method of claim 2, further comprising:
obtaining a plurality of discrete time values taken for the semiconductor processing equipment to perform each of the plurality of sub-operations from the semiconductor processing equipment.

5. The control method of claim 4, wherein the obtaining of the first time further comprises:
obtaining a first discrete time value taken for the semiconductor processing equipment to perform a first sub-operation corresponding to a first sub-command;
obtaining a second discrete time value taken for the semiconductor processing equipment to perform a second sub-operation corresponding to a second sub-command; and
adding the second discrete time value to the first discrete time value.

6. The control method of claim 4, further comprising:
determining, by a machine learning model, a time taken for the semiconductor processing equipment to perform the unit operation according to each of a plurality of setting values, based on the plurality of discrete time values; and
identifying the first setting value and the second setting value in which the time of the semiconductor processing equipment meets a predetermined criterion among the plurality of setting values.

7. The control method of claim 6, wherein the determining of the time of the semiconductor processing equipment according to each of the plurality of setting values by the machine learning model comprises:
outputting the plurality of sub-commands according to each of a plurality of different schedules, each being determined by each of the plurality of setting values; and
obtaining the time by adding the plurality of discrete time values taken for the semiconductor processing equipment to perform each of the plurality of sub-operations sequentially, based on the plurality of sub-commands.

8. The control method of claim 6, wherein the identifying of the first setting value and the second setting value comprises identifying the first setting value and the second setting value in which the time of the semiconductor processing equipment is less than a predetermined threshold among the plurality of setting values.

9. The control method of claim 2, wherein the obtaining of the second time comprises:
outputting the plurality of sub-commands according to a second schedule determined by the second setting value; and
obtaining the second time taken for the semiconductor processing equipment to perform the plurality of sub-operations sequentially, based on the plurality of sub-commands output according to the second schedule.

10. The control method of claim 1, further comprising:
obtaining a third time taken for the semiconductor processing equipment to perform the unit operation, according to a third setting value having at least one parameter of which differs from at least one of the parameters of the first setting value, while obtaining the first time;
obtaining a fourth time taken for the semiconductor processing equipment to perform the unit operation, according to a fourth setting value having at least one parameter of which differs from at least one parameter of the third setting value, while obtaining the second time; and
controlling the semiconductor processing equipment according to the first setting value, based on the first time among the first time, the second time, the third time, and the fourth time being smallest.

11. A control method for semiconductor processing equipment, the control method comprising:
outputting a plurality of sub-commands corresponding to a plurality of sub-operations constituting a unit operation sequentially according to a first schedule;
determining a first time taken for the semiconductor processing equipment to perform the unit operation, based on the plurality of sub-commands output according to the first schedule;
outputting the plurality of sub-commands sequentially according to a second schedule different from the first schedule;
obtaining a second time taken for the semiconductor processing equipment to perform the unit operation, based on the plurality of sub-commands output according to the second schedule; and
transmitting the plurality of sub-commands to the semiconductor processing equipment sequentially according to the first schedule, based on the first time being smaller than the second time.

12. The control method of claim 11, further comprising:
obtaining a plurality of discrete time values taken for the semiconductor processing equipment to perform each of the plurality of sub-operations from the semiconductor processing equipment.

13. The control method of claim 12, wherein the determining of the first time comprises:
obtaining a first discrete time value taken for the semiconductor processing equipment to perform a first sub-operation corresponding to a first sub-command;
obtaining a second discrete time value taken for the semiconductor processing equipment to perform a second sub-operation corresponding to a second sub-command; and
adding the second discrete time value to the first discrete time value.

14. The control method of claim 12, further comprising:
determining, by a machine learning model, a time taken for the semiconductor processing equipment to perform the unit operation according to each of a plurality of schedules, based on the plurality of discrete time values; and
identifying the first schedule and the second schedule in which the time of the semiconductor processing equipment meets a predetermined criterion among the plurality of schedules.

15. The control method of claim 14, wherein the determining of the time of the semiconductor processing equipment according to each of the plurality of schedules by the machine learning model comprises:
outputting the plurality of sub-commands according to each of the plurality of schedules; and
obtaining the time by adding the plurality of discrete time values taken for the semiconductor processing equipment to perform each of the plurality of sub-operations sequentially, based on the plurality of sub-commands.

16. The control method of claim 14, wherein the identifying of the first schedule and the second schedule comprises identifying the first schedule and the second schedule in which the time of the semiconductor processing equipment is less than a predetermined threshold among the plurality of schedules.

17. A control method for semiconductor processing equipment, the control method comprising:
obtaining a first time taken for the semiconductor processing equipment to perform a unit operation according to a first schedule determined by a plurality of parameters for controlling the semiconductor processing equipment;
obtaining a second time taken for the semiconductor processing equipment to perform the unit operation according to a second schedule different from the first schedule; and
controlling the semiconductor processing equipment according to the first schedule, based on the first time being smaller than the second time,
wherein the obtaining of the first time comprises obtaining the first time taken for the semiconductor processing equipment to perform a plurality of sub-operations constituting the unit operation sequentially, according to the first schedule.

18. The control method of claim 17, wherein the obtaining of the first time comprises:
outputting a plurality of sub-commands respectively corresponding to the plurality of sub-operations sequentially, according to the first schedule; and
obtaining the first time taken for the semiconductor processing equipment to perform the plurality of sub-operations sequentially, based on the plurality of sub-commands.

19. The control method of claim 18, wherein the controlling of the operation of the semiconductor processing equipment according to the first schedule comprises transmitting the plurality of sub-commands to the semiconductor processing equipment sequentially according to the first schedule.

20. The control method of claim 18, further comprising:
determining, by a machine learning model, a time taken for the semiconductor processing equipment to perform the unit operation according to each of a plurality of different schedules, based on a plurality of discrete time values taken for the semiconductor processing equipment to perform the plurality of sub-operations; and
identifying the first schedule and the second schedule in which the time of the semiconductor processing equipment meets a predetermined criterion among the first schedule and the second schedule.
